(19) United States
(12) Patent Application Publication
(10) Pub. No.: US 2026/0255805 A1
(43) Pub. Date: Aug. 27, 2026

(54) DISPLAY PANEL AND MANUFACTURING METHOD THEREOF

(71) Applicant: Guangzhou China Star Optoelectronics Semiconductor Display Technology Co., Ltd., Guangzhou (CN)

(72) Inventors: Bin ZHAO, Guangzhou (CN); Jun ZHAO, Guangzhou (CN); Xiaolin YAN, Guangzhou (CN); Shan LI, Guangzhou (CN); Jia TANG, Guangzhou (CN); Shuaiyi WANG, Guangzhou (CN)

(73) Assignee: Guangzhou China Star Optoelectronics Semiconductor Display Technology Co., Ltd., Guangzhou (CN)

(21) Appl. No.: 19/250,216

(22) Filed: Jun. 26, 2025

(30) Foreign Application Priority Data
Feb. 27, 2025 (CN) 202510229116.0

(51) Int. Cl. H10K 59/122; H10K 59/12

(52) U.S. Cl. CPC H10K 59/122; H10K 59/1201

(57) ABSTRACT

The present disclosure provides a display panel and a manufacturing method thereof. The manufacturing method includes: forming a thin film transistor structure layer, first electrodes, a first pixel defining layer (inorganic layer), and a second pixel defining layer (organic photoresist layer) on the substrate; patterning the second pixel definition layer to form first, second, and third photoresist strips which are cross-connected to define a plurality of openings; ashing the second pixel definition layer and etching the first pixel definition layer at the same time by using the second pixel definition layer as a mask, so as to remove the first photoresist strips, thin the second photoresist strips to form first retaining walls, thin the third photoresist strips to form second retaining walls, and etch the second pixel defining layer to form pixel openings exposing the first electrodes; and forming a light-emitting layer in the pixel openings.

### CROSS-REFERENCE TO RELATED APPLICATION

This application claims priority to Chinese Patent Application No. 202510229116.0, filed on Feb. 27, 2025. The disclosure of the aforementioned application is incorporated herein by reference in its entirety.

### TECHNICAL FIELD

The present disclosure relates to the field of display technologies, and in particular, to a display panel and a manufacturing method of the display panel.

### BACKGROUND

In conventional OLED display panels, a pixel definition layer is generally provided after oxide thin film transistors are formed. A pixel defining structure layer includes two organic pixel defining layers, one organic pixel defining layer includes first retaining walls extending along a lateral direction, the other organic pixel defining layer includes second retaining walls extending along a longitudinal direction, and the first retaining walls and the second retaining walls intersect to form pixel openings for printing ink materials. In addition, based on linear structures of the pixel definition layers, one color of ink is generally printed in one row or one column at the same time to reduce printing times and meet the accuracy requirement for printing.

In the course of research and practice of prior arts, the inventors of the present disclosure have found that a high temperature environment for a long time can lead to negative bias of oxide thin film transistors. Formation of a first organic pixel definition layer and a second organic pixel definition layer requires two thermal processes, and the two thermal processes easily lead to the risk of negative bias of the oxide thin film transistors. Secondly, in a process of performing ink baking, since the whole row or the whole column of the ink is communicated and a baking rate at an edge area of a display panel is greater than a baking rate at a middle area of the display panel, a solute in the middle area flows to the edge area with a solvent, resulting in uneven thickness of the light-emitting layer.

### SUMMARY

Embodiments of the present disclosure provide a manufacturing method of a display panel. The manufacturing method includes following steps:
forming a thin film transistor structure layer, first electrodes, a first pixel defining layer, and a second pixel defining layer in sequence on a substrate, the first pixel defining layer being an inorganic layer and the second pixel defining layer being an organic photoresist layer;
patterning the second pixel definition layer so that the second pixel definition layer includes first photoresist strips, second photoresist strips, and third photoresist strips, wherein the first photoresist strips and the second photoresist strips extend along a first direction and disposed at intervals in a second direction, the third photoresist strips extend along the second direction, the first direction intersects the second direction, the first photoresist strips and the second photoresist strips are cross-connected with the third photoresist strips to form a plurality of openings, a thickness of each of the first photoresist strips is less than a thickness of each of the second photoresist strips, the thickness of each of the second photoresist strips is less than a thickness of each of the third photoresist strips, each of the openings is disposed corresponding to one of the first electrodes, and in a top view, a pattern of each of the openings is within an area where a corresponding one of the first electrodes is located;
ashing the second pixel definition layer and etching the first pixel definition layer at the same time by using the second pixel definition layer as a mask, wherein the first photoresist strips are removed, the second photoresist strips are thinned to form first retaining walls, the third photoresist strips are thinned to form second retaining walls, and the second pixel defining layer is etched to form pixel openings exposing the first electrodes; and
forming a light-emitting layer in the pixel openings.

Embodiments of the present disclosure also provide a display panel, including:
a substrate;
a thin film transistor structure layer disposed on the substrate;
first electrodes disposed on one side of the thin film transistor structure layer away from the substrate;
a first pixel definition layer disposed on one side of the thin film transistor structure layer away from the substrate, wherein the first pixel definition layer is an inorganic layer, the first pixel definition layer includes a plurality of first pixel definition portions and a plurality of second pixel definition portions, and the first pixel definition portions and the second pixel definition portions are cross-connected to form a plurality of pixel openings exposing the first electrodes;
a second pixel definition layer disposed on one side of the first pixel definition layer away from the substrate, wherein the second pixel definition layer is an organic layer, the second pixel definition layer includes a plurality of first retaining walls and a plurality of second retaining walls, a thickness of each of the first retaining walls is less than a thickness of each of the second retaining walls, the first retaining walls and the first pixel definition portions extend along a first direction, the second retaining walls and the second pixel definition portions extend along a second direction intersecting the first direction, and at least two of the pixel openings are spaced between two adjacent ones of the first retaining walls in the second direction; and
a light-emitting layer covering the pixel openings.

### BRIEF DESCRIPTION OF THE DRAWINGS

FIG. 1 is a schematic flow diagram of a manufacturing method of a display panel according to embodiments of the present disclosure.

FIG. 2 is a schematic diagram of a structure corresponding to a step B101 of the manufacturing method of the display panel according to embodiments of the present disclosure.

FIG. 3 is a schematic diagram of a structure corresponding to a step B102 of the manufacturing method of the display panel according to embodiments of the present disclosure.

FIG. 4 is a schematic diagram of a structure corresponding to a step B103 of the manufacturing method of the display panel according to embodiments of the present disclosure.

FIG. 5 is a schematic diagram of a structure corresponding to a step B031 of the manufacturing method of the display panel according to embodiments of the present disclosure.

FIG. 6 is an enlarged view of a portion A1 in FIG. 5.

FIG. 7 is a schematic diagram of a structure corresponding to a step B032 of the manufacturing method of the display panel according to embodiments of the present disclosure.

FIG. 8 is an enlarged view of a portion A2 in FIG. 7.

FIG. 9 is a schematic diagram of a structure corresponding to a step B104 of the manufacturing method of the display panel according to embodiments of the present disclosure.

FIG. 10 is a schematic cross-sectional view taken along a line c1-c1 in FIG. 9.

FIG. 11 is a schematic diagram of a planar structure of a display panel according to embodiments of the present disclosure.

FIG. 12 is a schematic cross-sectional view taken along a line c2-c2 in FIG. 11.

### DETAILED DESCRIPTION

Hereinafter, the technical proposals in the embodiments of the present disclosure will be clearly and completely described with reference to the accompanying drawings in the embodiments of the present disclosure, and it is obvious that the described embodiments are only a part of the embodiments of the present disclosure, but not all the embodiments. Based on the embodiments in the present disclosure, all other embodiments obtained by those skilled in the art without creative work belong to the scope of protection of the present disclosure. Furthermore, it is to be understood that the detailed description described herein is for illustration and explanation only, and is not intended to limit the present disclosure. In the present disclosure, the various embodiments may be combined with each other but will not be described one by one. Unless otherwise stated, orientational terms such as “upper” and “lower” generally refer to the upper and lower in the actual use or working state of the device, specifically the drawing direction in the drawings. The terms “inside” and “outside” are for the outline of the device. The terms “first”, “second”, “third” etc. are used for indicative purposes only and do not impose numerical requirements or establish order.

Embodiments of the present disclosure provide a display panel and a manufacturing method of the display panel, which will be described in detail below. Note that the order of description of the following embodiments is not intended to limit the preferred order of the embodiments.

Referring to FIG. 1, embodiments of the present disclosure provide a manufacturing method of a display panel, and the manufacturing method includes steps of B101, B102, B103, and B104.

The step B101 includes: forming a thin film transistor structure layer, first electrodes, a first pixel defining layer, and a second pixel defining layer in sequence on the substrate, the first pixel defining layer being an inorganic layer and the second pixel defining layer being an organic photoresist layer.

The step B102 includes: patterning the second pixel definition layer so that the second pixel definition layer includes first photoresist strips, second photoresist strips, and third photoresist strips. The first photoresist strips and the second photoresist strips extend along a first direction and disposed at intervals in a second direction, the third photoresist strips extend along the second direction, the first direction intersects the second direction, the first photoresist strips and the second photoresist strips are cross-connected with the third photoresist strips to form a plurality of openings, a thickness of each of the first photoresist strips is less than a thickness of each of the second photoresist strips, the thickness of each of the second photoresist strips is less than a thickness of each of the third photoresist strips. Each of the openings is disposed corresponding to one of the first electrodes, and in a top view, the pattern of each of the openings is within an area where the corresponding one of the first electrodes is located.

The step B103 includes: ashing the second pixel definition layer and etching the first pixel definition layer at the same time by using the second pixel definition layer as a mask. The first photoresist strips are removed, the second photoresist strips are thinned to form first retaining walls, the third photoresist strips are thinned to form second retaining walls, and the second pixel defining layer is etched to form pixel openings exposing the first electrodes.

The step B104 includes: forming a light-emitting layer in the pixel openings.

It should be noted that the manufacturing method of the display panel in the embodiments of the present disclosure uses one photomask to form the patterned first pixel definition layer and the patterned second pixel definition layer, thereby saving one photomask manufacturing process. Moreover, the first pixel definition layer is an inorganic layer, so that one thermal manufacturing process is saved, thereby reducing a risk of negative bias of thin film transistors. Secondly, the second pixel defining layer is provided with first retaining walls in a second direction, so that a plurality of ink printing areas are defined in the second direction, and when a light-emitting layer is baked, a flow path of a solute flowing with a solvent is blocked, and in the whole panel, a risk of a large transfer of the solute in a middle area to an edge area is reduced, so as to improve a film thickness uniformity of the light-emitting layer.

Hereinafter, specific steps of the manufacturing method of the display panel according to the embodiments of the present disclosure will be described.

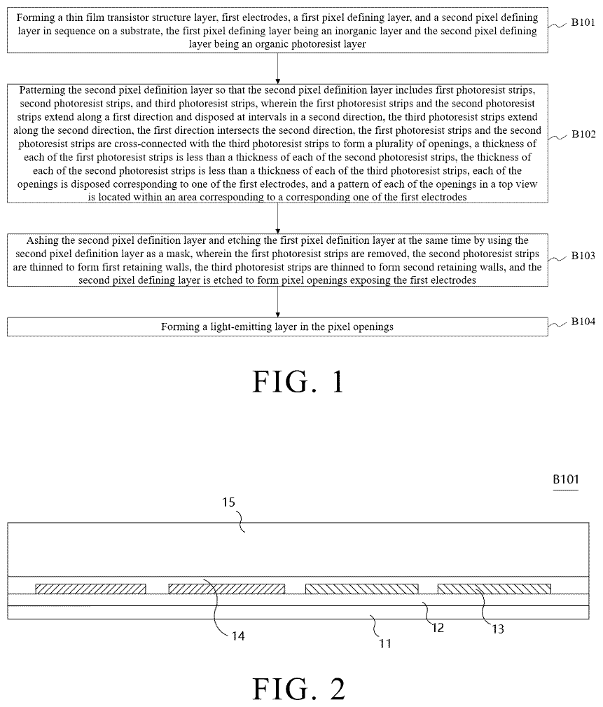

Referring to FIG. 2, in the step B101, a thin film transistor structure layer 12, first electrodes 13, a first pixel definition layer 14, and a second pixel definition layer 15 are sequentially formed on a substrate 11. The first pixel defining layer 14 is an inorganic layer, and the second pixel defining layer 15 is an organic photoresist layer.

It should be noted that, as compared with the prior art in which both pixel definition layers are organic layers, in the manufacturing method of the display panel in the embodiments of the present disclosure, a material of the first pixel definition layer 14 is set as an inorganic layer, which saves one thermal process affecting thin film transistors, and further reduces the risk of negative bias and stability degradation of the thin film transistors.

Optionally, the substrate 11 may be a rigid substrate or a flexible substrate. A material of the substrate 11 includes one of glass, sapphire, silicon, silicon dioxide, polyethylene, polypropylene, polystyrene, polylactic acid, polyethylene dicarboxylate, polyethylene terephthalate, polyethylene naphthalate, polycarbonate, polyethersulfone, aromatic fluorotoluene containing polyarylate, polycyclic olefin, polyimide, and polyurethane.

Optionally, the thin film transistor structure layer 12 includes elements such as thin film transistors and capacitors.

Optionally, a material of a channel of each of the thin film transistors may be an oxide semiconductor. The oxide semiconductor may include one of oxides based on titanium, hafnium, zirconium, aluminum, tantalum, germanium, zinc, gallium, tin, and indium, or one of composite oxides thereof, such as indium gallium zinc oxide, indium zinc oxide, zinc tin oxide, indium gallium oxide, indium tin oxide, indium tin oxide, indium zirconium oxide, indium zirconium zinc oxide, indium zirconium gallium oxide, indium zinc oxide, and hafnium indium zinc oxide.

Optionally, each of the first electrodes 13 may be an anode or a cathode, and in the embodiments of the present disclosure, the case where the first electrode 13 is an anode can be used as an example. Each of the first electrodes 13 is connected to a driving thin film transistor.

Optionally, the first pixel defining layer 14 may be formed by vapor deposition. A thickness of the first pixel definition layer 14 is less than a thickness of the second pixel definition layer 15.

A material of the second pixel definition layer 15 is an organic photoresist, and as compared with the non-organic photoresist, the manufacturing method of the embodiment of the present disclosure may not additionally provide a photoresist layer to pattern the second pixel definition layer 15, but may directly use the second pixel definition layer 15 as a photoresist mask layer.

Next, the manufacturing method proceeds to the step B102.

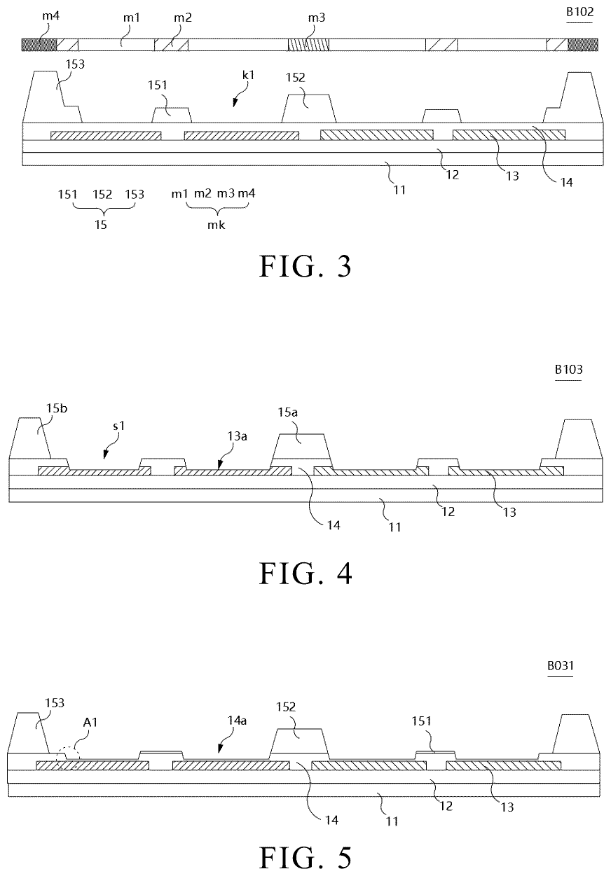

Referring to FIG. 3, in the step B102, the second pixel definition layer 15 is patterned.

The second pixel definition layer 15 includes first photoresist strips 151, second photoresist strips 152, and third photoresist strips 153. The first photoresist strips 151 and the second photoresist strips 152 extend along a first direction x and are disposed at intervals in a second direction y. The third photoresist strips 153 extend along the second direction y and are arranged at intervals along the first direction x. The first direction x intersects the second direction y. The first photoresist strips 151 and the second photoresist strips 152 are cross-connected with the third photoresist strips 153 to form a plurality of openings k1. A thickness of each of the first photoresist strips 151 is less than a thickness of each of the second photoresist strips 152. The thickness of each of the second photoresist strips 152 is less than a thickness of each of the third photoresist strips 153. Each of the openings k1 is provided corresponding to one of the first electrodes 13. A pattern of each of the openings k1 in a plan view is located within an area where a corresponding one of the first electrodes 13 is located.

Optionally, the first direction x and the second direction y intersect perpendicularly. The first direction x and the second direction y may be combined with the schematic diagram of FIG. 9.

It can be understood that the second pixel definition layer 15 is directly exposed and developed by using one mask mk to form the patterned second pixel definition layer 15, and the first pixel definition layer 14 is etched by using the patterned second pixel definition layer 15 as a mask, thereby achieving an effect of saving one mask manufacturing process.

Optionally, the mask mk includes first light-transmitting portions m1, second light-transmitting portions m2, third light-transmitting portions m3, and light-shielding portions m4. A light transmittance of the first light-transmitting portions m1, a light transmittance of the second light-transmitting portions m2, a light transmittance of the third light-transmitting portions m3, and a light transmittance of the light-shielding portions m4 gradually decreases, the light transmittance of the first light-transmitting portions m1 is 100%, and the light transmittance of the light-shielding portions m4 is 0%. Each of the first light-transmitting portions m1 corresponds to one of the openings k1, each of the second light-transmitting portions m2 corresponds to one of the first photoresist strips 151, each of the third light-transmitting portions m3 corresponds to one of the second photoresist strips 152, and each of the light shielding portions m4 corresponds to one of the third photoresist strips 153.

Optionally, in some embodiments, another first photoresist strip 151 is further connected to one side of each of the third photoresist strips 153 close to one corresponding opening k1, and an extending direction of the another first photoresist strip 151 is same as the third photoresist strip 153. In this way, each of the openings k1 is defined by two first photoresist strips 151 extending along the second direction y, one first photoresist strip 151 extending along the first direction x, and one second photoresist strip 152 extending along the first direction x. Since each opening k1 is defined by three first photoresist strips 151 of equal thickness, the depth uniformity of the opening k1 can be better controlled, and the depth uniformity of a subsequent pixel opening s1 can be further controlled, and the thickness uniformity of the light-emitting layer 16 can be improved.

Of course, in some embodiments, each of the openings k1 may be directly defined by two third photoresist strips 153, one first photoresist strip 151, and one second photoresist strip 152.

Next, the manufacturing method proceeds to the step B103.

Referring to FIG. 4, in the step B103, the first pixel definition layer 14 is etched at the same time as the second pixel definition layer 15 is ashed by using the second pixel definition layer 15 as the mask.

In the step B103, the first photoresist strips 151 are removed, the second photoresist strips 152 are thinned to form first retaining walls 15a, the third photoresist strips 153 are thinned to form second retaining walls 15b, and the second pixel definition layer 15 is etched to define pixel openings s1 exposing the first electrodes 13.

Optionally, in the step B102, a thickness of each of the first photoresist strips 151 is less than or equal to a thickness of the first pixel definition layer 14. In the step B103, a rate at which the first pixel defining layer 14 is etched is defined as a first rate, a rate at which the second pixel defining layer 15 is etched is defined as a second rate, and the second rate is less than the first rate.

It can be understood that the first pixel definition layer 14 and the second pixel definition layer 15 are etched through the same gas, and the rate of etching the first pixel definition layer 14 is greater than the rate of etching the second pixel definition layer 15, so that a required thickness of the second pixel definition layer 15 can be thinned based on the fact that the second pixel definition layer 15 is photoresist, and the first retaining walls 15a and the second retaining walls 15b can be kept thicker to separate the subsequent light-emitting layer 16 while saving costs.

Optionally, in some embodiments of the present disclosure, the thickness of the first pixel definition layer 14 is between 1500 angstroms and 5500 angstroms, such as 1500 angstroms, 2000 angstroms, 2500 angstroms, 3000 angstroms, 3500 angstroms, 4000 angstroms, 4500 angstroms, 5000 angstroms, or 5500 angstroms.

A thickness of each of the first retaining walls 15a is between 5500 angstroms and 10000 angstroms, such as 5500 angstroms, 6000 angstroms, 6500 angstroms, 7000 angstroms, 7500 angstroms, 8000 angstroms, 8500 angstroms, 9000 angstroms, 9500 angstroms, or 10000 angstroms.

A thickness of each of the second retaining walls 15b is between 6000 angstroms and 15000 angstroms, such as 6000 angstroms, 6500 angstroms, 7000 angstroms, 7500 angstroms, 8000 angstroms, 8500 angstroms, 9000 angstroms, 9500 angstroms, 10000 angstroms, 10500 angstroms, 11000 angstroms, 11500 angstroms, 12000 angstroms, 12500 angstroms, 13000 angstroms, 13000 angstroms, 14000 angstroms, 14500 angstroms, or 15000 angstroms.

It can be understood that the first retaining walls 15a and the second retaining walls 15b are all used to block ink materials of the light-emitting layer 16 from communicating with each other, so as to avoid the case where the ink materials of the light-emitting layer 16 are communicated in an entire column or an entire row. The first retaining walls 15a are arranged at intervals along the second direction y to divide each column of light-emitting layer 16 into a plurality of areas, so as to avoid the risk of solutes migrating with solvents, thereby improving the thickness uniformity of the light-emitting layer 16.

Optionally, in some embodiments, the thickness of each of the first retaining walls 15a is less than the thickness of each of the second retaining walls 15b. It can be understood that when the ink materials of the light-emitting layer 16 is subsequently baked, the thinner first retaining walls 15a can allow a part of the air pressure to be slowly released in the second direction y, and the risk of local high pressure is reduced. For example, in an initial baking stage, a solvent volatilization rate is relative fast, and the thinner first retaining walls 15a can buffer the sudden rise of air pressure, thereby reducing the risk of solute being pushed to the edge by high pressure, and reducing the risk of sudden change of film thickness. In addition, based on the fact that the first retaining walls 15a are thin, the air pressure gradient difference between the central area and the two sides areas of the display panel is reduced by the moderate air pressure release in the second direction y, and the driving force for solute to migrate to the edge is reduced, thereby providing uniformity of the baking atmosphere to improve the thickness uniformity of the subsequent light-emitting layer 16.

In addition, since the second retaining walls 15b are thick, the second retaining walls 15b can provide stronger mechanical support, and the first retaining walls 15a are thin so that there is a height difference between the first retaining walls 15a and the second retaining walls 15b, and this height difference can buffer the impact of external forces to better protect the display panel. Secondly, the thinning of the first retaining walls 15a can reduce the shielding of edges of the pixel openings s1, thereby improving the opening ratio, and enhancing the display brightness.

Optionally, in the step B103, each of the first electrode 13 is etched to form a groove 13a communicating with a corresponding one of the pixel openings s1.

It can be understood that the groove 13a is defined in each of the first electrodes 13, so as to ensure that an area of each of the pixel openings s1 is free of the material of the first pixel defining layer 14, and to reduce the risk that the material of the first pixel defining layer 14 remains in the pixel openings s1.

Optionally, in some embodiments, in the step B103, the gas may be controlled to not etch the first electrodes 13.

Optionally, in some embodiments of the present disclosure, in the step B103, the pixel openings s1 may be formed by one etching process.

Optionally, in some embodiments of the present disclosure, in the step B103, two etching processes may be used to form the pixel openings s1. For example, the step B103 includes the following steps of B031 and B032.

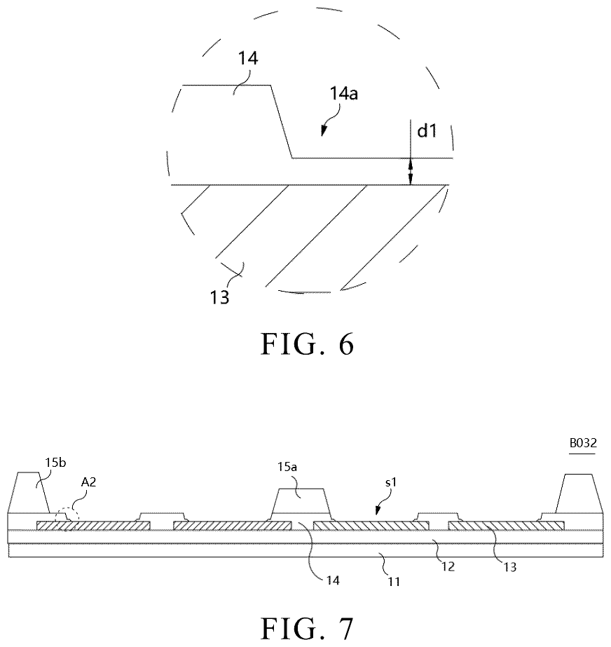

Referring to FIG. 5 and FIG. 6, in the step B031, the first pixel definition layer 14 and the second pixel definition layer 15 are simultaneously etched through a first gas, so that the second pixel definition layer 15 is thinned, recessed grooves 14a are formed in the first pixel definition layer 14, and a distance d1 from a bottom surface of each of the recessed grooves 14a to a corresponding one of the first electrodes 13 is between 10 nm and 80 nm.

Optionally, the distance d1 from the bottom surface of each of the recessed grooves 14a to the corresponding one of the first electrodes 13 may be 10 nm, 20 nm, 30 nm, 40 nm, 50 nm, 60 nm, 70 nm, or 80 nm.

Next, the manufacturing method proceeds to the step B032.

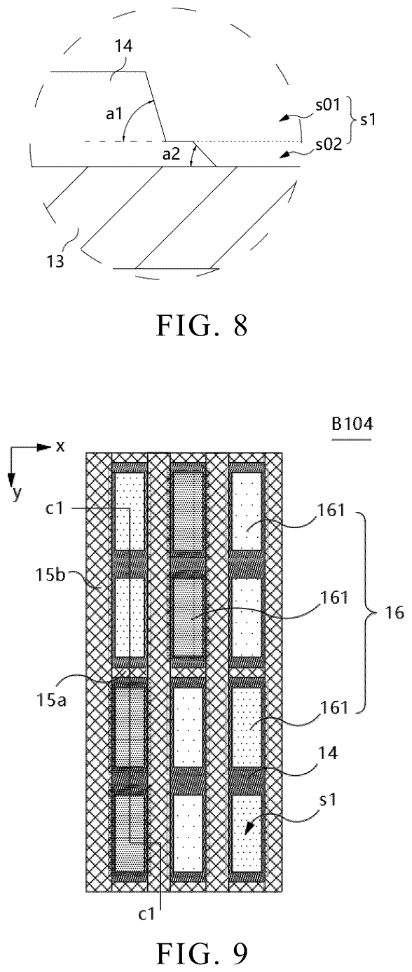

Referring to FIG. 7 and FIG. 8, in the step B032, the first pixel defining layer 14 and the second pixel defining layer 15 are simultaneously etched through a second gas, so that the first photoresist strips 151 are removed, the second photoresist strips 152 are thinned to form the first retaining walls 15a, the third photoresist strips 153 are thinned to form the second retaining walls 15b, and the second pixel defining layer 15 is etched to form the pixel openings s1 exposing the first electrodes 13. The rate at which the second gas etches the first electrodes 13 is less than the rate at which the first gas etches the first electrodes 13.

It should be noted that each of the first gas and the second gas may be a single etching gas or a mixed gas of at least two gases.

It can be understood that by etching the first pixel defining layer 14 and the second pixel defining layer 15 twice through two gases, the risk of over-etching the first electrodes 13 can be reduced.

The time when the distance d1 from the bottom surface of the recessed groove 14a to the first electrode 13 is between 10 nanometers and 80 nanometers is used as the time for switching to secondary etching, and since the rate at which the second gas etches the first electrode 13 is less than the rate at which the first gas etches the first electrode 13, the overall etching time will not last for too long, reducing the risk of excessive etching of the first electrodes 13.

It can be understood that, in some embodiments, each of the pixel openings s1 is a stepped opening based on the two etching processes in the step B103.

Each of the pixel openings s1 includes a first opening s01 and a second opening s02. The first opening s01 communicates with one side of the second opening s02 away from the substrate 11, an opening width of the first opening s01 is greater than an opening width of the second opening s02, and a depth of the first opening s01 is greater than a depth of the second opening s02.

Each of the pixel openings s1 is a stepped opening, which can improve the continuity of subsequent film layer coverage and reduce the risk of fracture. Secondly, each of the pixel openings s1 having the stepped structure can disperse the capillary force and reduce the risk of concentrated accumulation of edge liquid under a single slope.

Optionally, in some embodiments, a slope a2 of the second opening s02 is less than a slope a1 of the first opening s01. As can be understood, when the slope of the second opening s02 is gentle, the capillary flow of ink at the bottom can be gentler, and the tendency of edge gathering is reduced. The relative steep slope of the first opening s01 may reduce an accumulation rate of liquid film at the edge by limiting the lateral flow in a top area. That is, by adjusting the slope of the first opening s01 and the slope of the second opening s02, it is possible to reduce the risk of the ink material accumulating at edges of the pixel openings s1, thereby improving the thickness uniformity of the light-emitting layer 16.

Optionally, in some embodiments of the present disclosure, in the step B103, an ashing temperature is between 10 degrees Celsius and 40 degrees Celsius, such as 10 degrees Celsius, 15 degrees Celsius, 20 degrees Celsius, 25 degrees Celsius, 30 degrees Celsius, 35 degrees Celsius, or 40 degrees Celsius.

It can be understood that an ambient temperature in the step B103 is low and does not affect the stability of the thin film transistors.

Next, the manufacturing method proceeds to the step B104.

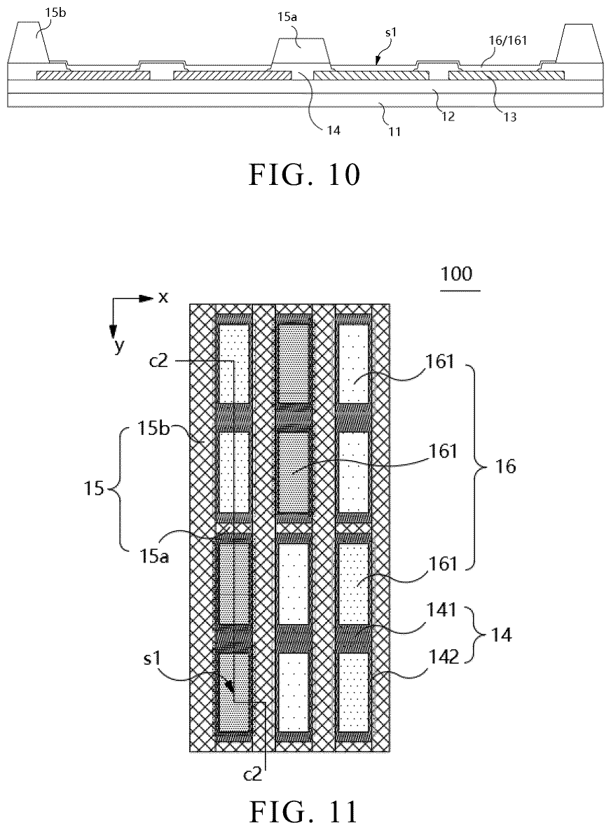

Referring to FIG. 9 and FIG. 10, in the step B104, the light-emitting layer 16 is formed in the pixel openings s1.

Optionally, in some embodiments of the present disclosure, in the second direction y, a plurality of the first retaining walls 15a are arranged at intervals, and at least two pixel openings s1 are spaced between two adjacent first retaining walls 15a.

In the step B104, the light-emitting layer 16 is formed in the pixel openings s1 by ink-jet printing. The light-emitting layer 16 includes a plurality of light-emitting portions 161, and each light-emitting portion 161 continuously covers at least two pixel openings s1. In the second direction y, one first retaining wall 15a is spaced between two adjacent light-emitting portions 161, and in the first direction x, one second retaining wall 15b is spaced between two adjacent light-emitting portions 161.

It can be understood that each light-emitting portion 161 continuously covers at least two pixel openings s1, so one nozzle is used to print at least two pixel openings s1 correspondingly, and multiple drops of ink can be printed at one time so that the ink flows between two adjacent pixel openings s1, but is blocked by the first retaining walls 15a and the second retaining walls 15b. Based on this, compared with the conventional method in which one nozzle corresponds to one pixel opening, the embodiments of the present disclosure can reduce the printing accuracy requirement for the nozzle and improve the printing efficiency.

Furthermore, ink does not flow between the two pixel openings s1 adjacent to one same first retaining wall 15a, and ink does not flow between the two pixel openings s1 adjacent to one same second retaining wall 15b.

Based on this, optionally, in some embodiments of the present disclosure, colors of any two adjacent light-emitting portions 161 are different from each other.

Compared to the solution that the two adjacent light-emitting portions 161 have the same color in the second direction y, the colors of the two adjacent light-emitting portions 161 are different from each other in the embodiments of the present disclosure, so the light-emitting uniformity of the display panel can be improved.

Optionally, in some embodiments of the present disclosure, two adjacent light-emitting portions 161 have the same color in the second direction y. For example, the colors of one entire column of the light-emitting portions 161 are the same.

Optionally, in some embodiments, other light-emitting functional layers, such as a hole injection layer and a hole transport layer, may be printed in addition to the light-emitting layer 16. Secondly, an electron transport layer and an electron injection layer may be formed on the light-emitting layer 16.

Subsequently, a cathode and an encapsulation layer may also be formed on the light-emitting layer 16.

Thus, the manufacturing method of the display panel in the embodiments of the present disclosure is completed.

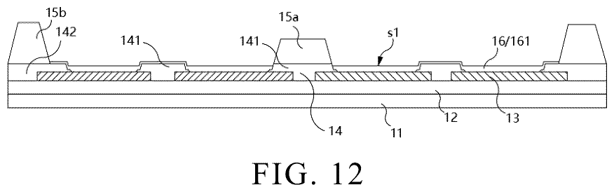

Referring to FIG. 11 and FIG. 12, correspondingly, the embodiments of the present disclosure further provide a display panel 100 including a substrate 11, a thin film transistor structure layer 12, first electrodes 13, a first pixel defining layer 14, a second pixel defining layer 15, and a light-emitting layer 16.

The thin film transistor structure layer 12 is disposed on the substrate 11. The first electrodes 13 are disposed on one side of the thin film transistor structure layer 12 away from the substrate 11.

The first pixel defining layer 14 is disposed on the side of the thin film transistor structure layer 12 away from the substrate 11. The first pixel definition layer 14 is an inorganic layer. The first pixel definition layer 14 includes a plurality of first pixel definition portions 141 and a plurality of second pixel definition portions 142. The first pixel defining portions 141 and the second pixel defining portions 142 are cross-connected to form a plurality of pixel openings s1 exposing the first electrodes 13.

The second pixel definition layer 15 is disposed on one side of the first pixel definition layer 14 away from the substrate 11, and the second pixel definition layer 15 is an organic layer. The second pixel defining layer 15 includes a plurality of first retaining walls 15a and a plurality of second retaining walls 15b, and a thickness of each of the first retaining walls 15a is less than a thickness of each of the second retaining walls 15b. The first retaining walls 15a and the first pixel defining portions 141 extend along a first direction x. The second retaining walls 15b and the second pixel defining portions 142 extend along a second direction y intersecting the first direction x. In the second direction y, at least two pixel openings s1 are spaced between two adjacent first retaining walls 15a.

The light-emitting layer 16 covers the pixel openings s1.

It should be noted that the display panel 100 in the embodiments of the present disclosure is manufactured by the manufacturing method described in any one of the above embodiments.

It should be noted that, as compared with the prior art in which both pixel definition layers are organic layers, in the display panel in the embodiments of the present disclosure, the material of the first pixel definition layer 14 is set as an inorganic layer, which saves one thermal process affecting thin film transistors, and further reduces the risk of negative bias and stability degradation of the thin film transistors.

Secondly, the first retaining walls 15a and the second retaining walls 15b are all used to block ink materials of the light-emitting layer 16 from communicating with each other, so as to avoid the case where the ink materials of the light-emitting layer 16 are communicated in an entire column or an entire row. The first retaining walls 15a are arranged at intervals along the second direction y to divide each column of light-emitting layer 16 into a plurality of areas, so as to avoid the risk that solutes migrate with solvents, thereby improving the thickness uniformity of the light-emitting layer 16.

Since the thickness of each of the first retaining walls 15a is less than the thickness of each of the second retaining walls 15b, it can be understood that when the ink materials of the light-emitting layer 16 is subsequently baked, the thinner first retaining walls 15a can allow a part of the air pressure to be slowly released in the second direction y, and the risk of local high pressure is reduced. For example, in an initial baking stage, a solvent volatilization rate is relative fast, and the thinner first retaining walls 15a can buffer the sudden rise of air pressure, thereby reducing the risk of solute being pushed to the edge by high pressure, and reducing the risk of sudden change of film thickness. In addition, based on the fact that the first retaining walls 15aare thin, the air pressure gradient difference between the central area and the two sides areas of the display panel is reduced by the moderate air pressure release in the second direction y, and the driving force for the solute to migrate to the edge is reduced, thereby providing uniformity of the baking atmosphere, so as to improve the thickness uniformity of the subsequent light-emitting layer 16.

In addition, since the second retaining walls 15b are thick, the second retaining walls 15b can provide stronger mechanical support, and the first retaining walls 15a are thin so that there is a height difference between the first retaining walls 15a and the second retaining walls 15b, and this height difference can buffer the impact of external forces to better protect the display panel. Secondly, the thinning of the first retaining walls 15a can reduce the shielding of edges of the pixel openings s1, thereby improving the opening ratio, and enhancing the display brightness.

Optionally, in some embodiments of the present disclosure, the light-emitting layer 16 includes a plurality of light-emitting portions 161. Each of the light-emitting portion 161 continuously covers at least two pixel openings s1. In the second direction y, one first retaining wall 15a is spaced between two adjacent light-emitting portions 161, and in the first direction x, one second retaining wall 15b is spaced between two adjacent light-emitting portions 161.

In the second direction y, colors of any two adjacent light-emitting portions 161 are the same or different from each other.

It can be understood that the colors of the two adjacent light-emitting portions 161 in the second direction y are the same. The colors of the two adjacent light-emitting portions 161 are different from each other in the embodiments of the present disclosure, so the light-emitting uniformity of the display panel can be improved.

Optionally, with reference to FIG. 8, in some embodiments of the present disclosure, each of the pixel openings s1 includes a first opening s01 and a second opening s02. The first opening s01 communicates with one side of the second opening s02 away from the substrate 11, an opening width of the first opening s01 is greater than an opening width of the second opening s02, and a depth of the first opening s01 is greater than a depth of the second opening s02.

Each of the pixel openings s1 is a stepped opening, which can improve the continuity of subsequent film layer coverage and reduce the risk of fracture. Secondly, each of the pixel openings s1 having the stepped structure can disperse the capillary force and reduce the risk of concentrated accumulation of edge liquid under a single slope.

Optionally, in some embodiments, a slope a2 of the second opening s02 is less than a slope a1 of the first opening s01. As can be understood, when the slope of the second opening s02 is gentle, the capillary flow of ink at the bottom can be gentler, and the tendency of edge gathering is reduced. The relative steep slope of the first opening s01 may reduce an accumulation rate of liquid film at the edge by limiting the lateral flow in a top area. That is, by adjusting the slope of the first opening s01 and the slope of the second opening s02, it is possible to reduce the risk of the ink material accumulating at edges of the pixel openings s1, thereby improving the thickness uniformity of the light-emitting layer 16.

In the display panel 100 in the embodiments of the present disclosure, one photomask is adopted to pattern the first pixel definition layer 14 and the second pixel definition layer 15, thereby saving one photomask manufacturing process. Moreover, the first pixel definition layer 14 is an inorganic layer, so that one thermal manufacturing process is saved, thereby reducing the risk of negative bias of thin film transistors. Secondly, the second pixel defining layer 15 is provided with the first retaining walls 15a in the second direction y, so that a plurality of ink printing areas are defined in the second direction y, and when the light-emitting layer is baked, a flow path allowing a solute to flow with a solvent is blocked, and in the whole panel, a risk of a large transfer of the solute in a middle area to an edge area is reduced, so as to improve a film thickness uniformity of the light-emitting layer.

The display panel and the manufacturing method of the display panel provided in embodiments of the present disclosure have been described in detail above. The principles and embodiments of the present disclosure have been described herein by applying specific examples, and the description of the above embodiments is only for helping to understand the technical proposals and core ideas of the present disclosure. Meanwhile, those skilled in the art may change the specific embodiments and the scope of application according to the ideas of the present disclosure. Iin summary, the contents of the present specification should not be construed as limiting the present disclosure.

What is claimed is:

1. A manufacturing method of a display panel, comprising the following steps:
forming a thin film transistor structure layer, first electrodes, a first pixel defining layer, and a second pixel defining layer in sequence on a substrate, wherein the first pixel defining layer is an inorganic layer and the second pixel defining layer is an organic photoresist layer;
patterning the second pixel definition layer so that the second pixel definition layer comprises first photoresist strips, second photoresist strips, and third photoresist strips, wherein the first photoresist strips and the second photoresist strips extend along a first direction and disposed at intervals in a second direction, the third photoresist strips extend along the second direction, the first direction intersects the second direction, the first photoresist strips and the second photoresist strips are cross-connected with the third photoresist strips to form a plurality of openings, a thickness of each of the first photoresist strips is less than a thickness of each of the second photoresist strips, the thickness of each of the second photoresist strips is less than a thickness of each of the third photoresist strips, each of the openings is disposed corresponding to one of the first electrodes, and in a top view, a pattern of each of the openings is within an area where a corresponding one of the first electrodes is located;
ashing the second pixel definition layer and etching the first pixel definition layer at the same time by using the second pixel definition layer as a mask, wherein the first photoresist strips are removed, the second photoresist strips are thinned to form first retaining walls, the third photoresist strips are thinned to form second retaining walls, and the second pixel defining layer is etched to form pixel openings exposing the first electrodes; and
forming a light-emitting layer in the pixel openings.

2. The manufacturing method of the display panel according to claim 1, wherein in the step of forming the thin film transistor structure layer, the first electrodes, the first pixel defining layer, and the second pixel defining layer in sequence on the substrate, the first pixel defining layer is formed by vapor deposition.

3. The manufacturing method of the display panel according to claim 1, wherein in the step of forming the thin film transistor structure layer, the first electrodes, the first pixel defining layer, and the second pixel defining layer in sequence on the substrate, a thickness of the first pixel definition layer is less than a thickness of the second pixel definition layer.

4. The manufacturing method of the display panel according to claim 1, wherein in the step of patterning the second pixel definition layer, the second pixel definition layer is directly exposed and developed by using one mask;
the mask comprises first light-transmitting portions corresponding to positions where the openings are to be formed, second light-transmitting portions corresponding to positions where the first photoresist strips are to be formed, third light-transmitting portions corresponding to positions where the second photoresist strips are to be formed, and light-shielding portions corresponding to positions where the third photoresist strips are to be formed;
a light transmittance of the first light-transmitting portions, a light transmittance of the second light-transmitting portions, a light transmittance of the third light-transmitting portions, and a light transmittance of the light-shielding portions gradually decreases; and
the light transmittance of the first light-transmitting portions is 100%, and the light transmittance of the light-shielding portions is 0%.

5. The manufacturing method of the display panel according to claim 1, wherein in the step of ashing the second pixel definition layer and etching the first pixel definition layer at the same time by using the second pixel definition layer as the mask, the thickness of each of the first photoresist strips is less than or equal to a thickness of the first pixel definition layer, a rate of etching the first pixel definition layer is defined as a first rate, a rate of etching the second pixel definition layer is defined as a second rate, and the second rate is less than the first rate.

6. The manufacturing method of the display panel according to claim 5, wherein the thickness of the first pixel defining layer is between 1500 angstroms and 5500 angstroms, a thickness of each of the first retaining walls is between 5500 angstroms and 10000 angstroms, and a thickness of each of the second retaining walls is between 6000 angstroms and 15000 angstroms.

7. The manufacturing method of the display panel according to claim 1, wherein in the step of ashing the second pixel definition layer and etching the first pixel definition layer at the same time by using the second pixel definition layer as the mask, each of the first electrodes is etched to form a groove communicating with a corresponding one of the pixel openings.

8. The manufacturing method of the display panel according to claim 1, wherein in the step of ashing the second pixel definition layer and etching the first pixel definition layer at the same time by using the second pixel definition layer as the mask, the first electrodes are not etched.

9. The manufacturing method of the display panel according to claim 1, wherein in the step of ashing the second pixel definition layer and etching the first pixel definition layer at the same time by using the second pixel definition layer as the mask, a thickness of each of the first retaining walls is less than a thickness of each of the second retaining walls.

10. The manufacturing method of the display panel according to claim 1, wherein in the step of ashing the second pixel definition layer and etching the first pixel definition layer at the same time by using the second pixel definition layer as the mask, the first pixel definition layer and the second pixel definition layer are etched through a same gas, and a rate of etching the first pixel definition layer is greater than a rate of etching the second pixel definition layer.

11. The manufacturing method of the display panel according to claim 1, wherein the step of ashing the second pixel definition layer and etching the first pixel definition layer at the same time by using the second pixel definition layer as the mask comprises following steps:
simultaneously etching the first pixel definition layer and the second pixel definition layer using a first gas so that the second pixel definition layer is thinned, the first pixel definition layer forms recessed grooves, and a distance from a bottom surface of each of the recessed grooves to a corresponding one of the first electrodes is between 10 nanometers and 80 nanometers; and
simultaneously etching the first pixel defining layer and the second pixel defining layer using a second gas so that the first photoresist strips are removed, the second photoresist strips are thinned to form the first retaining walls, the third photoresist strips are thinned to form the second retaining walls, and the second pixel defining layer is etched to form the pixel openings exposing the first electrodes, wherein a rate at which the second gas etches the first electrode is less than a rate at which the first gas etches the first electrode.

12. The manufacturing method of the display panel according to claim 11, wherein each of the pixel openings is a stepped opening, the stepped opening comprises a first opening and a second opening, and the first opening communicates with one side of the second opening away from the substrate.

13. The manufacturing method of the display panel according to claim 12, wherein an opening width of the first opening is greater than an opening width of the second opening, and a depth of the first opening is greater than a depth of the second opening.

14. The manufacturing method of the display panel according to claim 12, wherein a slope of the second opening is less than a slope of the first opening.

15. The manufacturing method of the display panel according to claim 1, wherein in the step of ashing the second pixel definition layer and etching the first pixel definition layer at the same time by using the second pixel definition layer as the mask, an ashing temperature is between 10 degrees Celsius and 40 degrees Celsius.

16. The manufacturing method of the display panel according to claim 1, wherein in the second direction, a plurality of the first retaining walls are arranged at intervals, and at least two of the pixel openings are spaced between two adjacent ones of the first retaining walls; and
in the step of forming the light-emitting layer in the pixel openings, the light-emitting layer is formed in the pixel openings by ink-jet printing, the light-emitting layer comprises a plurality of light-emitting portions, each of the plurality of light-emitting portions continuously covers at least two of the pixel openings, one of the first retaining walls is spaced between two adjacent ones of the light-emitting portions in the second direction, and one of the second retaining walls is spaced between two adjacent ones of the light-emitting portions in the first direction.

17. The manufacturing method of the display panel according to claim 16, wherein colors of any two adjacent ones of the light-emitting portions are different from each other.

18. A display panel, comprising:
a substrate;
a thin film transistor structure layer disposed on the substrate;
first electrodes disposed on one side of the thin film transistor structure layer away from the substrate;
a first pixel definition layer disposed on one side of the thin film transistor structure layer away from the substrate, wherein the first pixel definition layer is an inorganic layer, the first pixel definition layer comprises a plurality of first pixel definition portions and a plurality of second pixel definition portions, and the first pixel definition portions and the second pixel definition portions are cross-connected to form a plurality of pixel openings exposing the first electrodes;
a second pixel definition layer disposed on one side of the first pixel definition layer away from the substrate, wherein the second pixel definition layer is an organic layer, the second pixel definition layer comprises a plurality of first retaining walls and a plurality of second retaining walls, a thickness of each of the first retaining walls is less than a thickness of each of the second retaining walls, the first retaining walls and the first pixel definition portions extend along a first direction, the second retaining walls and the second pixel definition portions extend along a second direction intersecting the first direction, and at least two of the pixel openings are spaced between two adjacent ones of the first retaining walls in the second direction; and
a light-emitting layer covering the pixel openings.

19. The display panel according to claim 18, wherein the light-emitting layer comprises a plurality of light-emitting portions, each of the light-emitting portions continuously covers at least two of the pixel openings, one of the first retaining walls is spaced between two adjacent ones of the light-emitting portions in the second direction, and one of the second retaining walls is spaced between two adjacent ones of the light-emitting portions in the first direction; and
in the second direction, colors of any two adjacent ones of the light-emitting portions are the same or different from each other.

20. The display panel according to claim 19, wherein each of the pixel openings comprises a first opening and a second opening, the first opening communicates with one side of the second opening away from the substrate, an opening width of the first opening is greater than an opening width of the second opening, and a depth of the first opening is greater than a depth of the second opening.
